(19) United States
(12) Patent Application Publication
(10) Pub. No.: US 2005/0219002 A1
(43) Pub. Date: Oct. 6, 2005

(54) Tuning an oscillator

(76) Inventors: Vikram Magoon, San Diego, CA (US); Georgios Asmanis, San Diego, CA (US)

Correspondence Address: TROP PRUNER & HU, PC, 8554 KATY FREEWAY, SUITE 100, HOUSTON, TX, 77024, US

(21) Appl. No.: 10/814,406

(22) Filed: Mar. 31, 2004

(51) Int. Cl. H03L 7/00

(52) U.S. Cl. 331/36 C

(57) ABSTRACT

A technique includes selectively coupling capacitors of oscillator stages together to set an oscillation frequency. In some embodiments of the invention, the capacitors may be formed primarily from parasitic capacitance.

### BACKGROUND

The invention generally relates to tuning an oscillator.

An oscillator typically includes inductors and capacitors for purposes of forming a resonant frequency of oscillation. More specifically, the oscillator may include various stages, each of which includes an arrangement of inductors and capacitors, called “an LC tank.” Ideally, only a minimal resistance should be coupled to the LC tank, as such resistance may affect the performance of the oscillator. However, many conventional oscillator topologies contain switches (typically metal-oxide-semiconductor field-effect-transistor (MOSFET) devices, for example), and these switches may potentially introduce a significant amount of resistance that is coupled to the LC tank. These switches may be selectively activated for purposes of tuning the oscillator, for example. One way to minimize the resistance that is coupled to the LC tank is to use relatively large switches (MOSFETs that have relatively large aspect ratios, for example).

As a more specific example, a voltage controlled oscillator (VCO) typically includes one or more oscillation stages, and each of these stages may include switches and an LC tank. The oscillation frequency of the VCO may be controlled by adjusting the magnitude of a tuning voltage. Ideally, the oscillation frequency linearly varies with the magnitude of the tuning voltage. More particularly, the relationship between the tuning voltage and the oscillation frequency (often referred to as the “tuning curve”) typically is monotonic in that a higher tuning voltage produces a higher oscillation frequency. However, when the effective resistance that is coupled to the LC tank becomes significant for a particular oscillator topology, the monotonicity of the tuning curve may be degraded. For example, above a certain tuning voltage, inversion of the tuning curve may occur in that the frequency of the oscillation may actually undesirably decrease instead of increase with the tuning voltage.

A potential challenge in using large MOSFET devices is that these large MOSFET devices typically consume a considerable amount of die area and may introduce a considerable amount of parasitic capacitance. Thus, there is a continuing need for better ways to decrease the resistance that is coupled to the LC tank of an oscillator.

### BRIEF DESCRIPTION OF THE DRAWING

FIG. 1 is flow diagram depicting a technique in accordance with an embodiment of the invention.

FIG. 2 is a schematic diagram depicting an oscillator according to an embodiment of the invention.

FIG. 3 is a schematic diagram of a differential switch according to an embodiment of the invention.

FIG. 4 is a schematic diagram of an oscillator core according to an embodiment of the invention.

FIGS. 5, 6, 7, 8 and 9 are waveforms depicting tuning curves of the oscillator versus switch resistances of the oscillator.

FIG. 10 is a schematic diagram depicting a metal-to-metal capacitor according to an embodiment of the invention.

FIG. 11 is a schematic diagram of an oscillator according to an embodiment of the invention.

FIGS. 12 and 13 depict tuning curves for the oscillator for different operating frequency ranges according to an embodiment of the invention.

FIG. 14 depicts a transmitter in accordance with an embodiment of the invention.

FIG. 15 depicts a receiver in accordance with an embodiment of the invention.

### DETAILED DESCRIPTION

The oscillation frequency of an oscillator typically is controlled by adjusting the inductance and/or capacitance of one or more LC tanks of the oscillator. This adjustment may be performed, for example, by using a varactor, a capacitor that has an adjustable capacitance. Alternatively, a tunable inductor may be used. Another way to tune the oscillator may be through the use of bank capacitors that are selectively coupled to the LC tank(s) to adjust the oscillation frequency.

For example, the oscillator may include a bank of capacitors that have capacitances that are binarily-weighted. Due to this arrangement, the appropriate capacitor(s) may be coupled to the LC tank for purposes of setting the operating frequency of the oscillator. A potential challenge with this arrangement, however, is that the switch(es) that are used to couple the capacitor(s) to the LC tank(s) may introduce significant resistances and severely degrade the monotonicity of the tuning curve for the oscillator. Typically, the switch(es) that are used to couple the capacitor(s) to the LC tank(s) are single-ended. In other words, each switch has one terminal coupled to the capacitor, and the other terminal of the switch is coupled to ground.

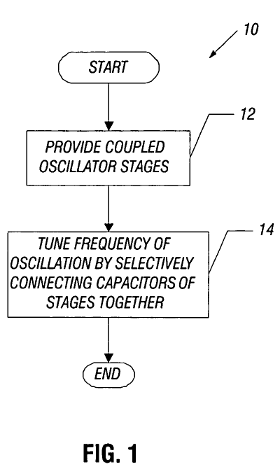

However, referring to FIG. 1, in accordance with an embodiment of the invention, a technique 10 uses differential switches, instead of single-ended switches, to tune an oscillator. More specifically, in some embodiments of the invention, the technique 10 is for use with an oscillator that has multiple (two, for example) coupled oscillator stages, as depicted in block 12. These oscillator stages may provide orthogonal output signals, in some embodiments of the invention. For example, one of the oscillator stages may provide a sine wave signal at its output terminal, and another one of the oscillator stages may provide a cosine wave signal at its output terminal. These signals are orthogonal, in that the sine and cosine signals are separated in phase by ninety degrees.

The differential switch topology described herein allows the use of relatively smaller metal-oxide-semiconductor field-effect-transistor (MOSFET) devices, as compared to their single-ended counterparts. More specifically, in accordance with the technique 10, the frequency of the oscillator is tuned by selectively connecting capacitors of the two stages together, as depicted in block 14. As described below, this technique of coupling capacitors from the stages together via differential switches reduces the switching losses for a given size MOSFET, reduces the effective resistance seen by the LC tank and thus, improves monotonicity characteristic of the tuning curve for the oscillator.

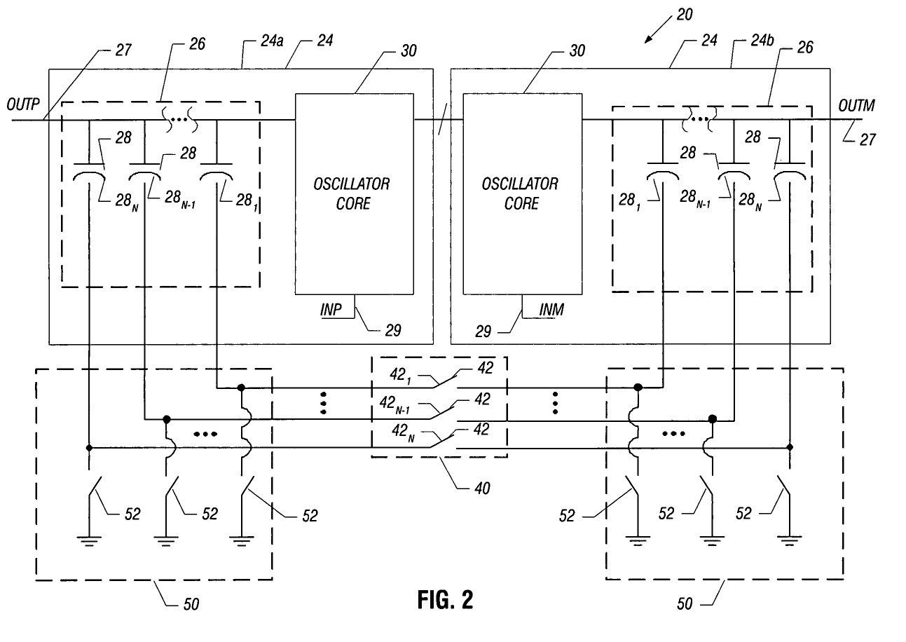

As a more specific example, FIG. 2 depicts an oscillator 20 in accordance with an embodiment of the invention. The oscillator 20 includes two oscillator stages 24a and 24b, that share a common design 24.

The oscillator stage 24 includes an output terminal 27 that furnishes an oscillation signal. The oscillation signals appearing at the output terminals 27 of the two stages 24a and 24b are orthogonal to each other. For example, the oscillator stage 24a provides an output signal (called OUTP), and the output terminal 27 of the oscillator stage 24b provides a signal (called OUTM). The OUTP and OUTM signals are orthogonal to each other. More specifically, the OUTP signal may be, for example, a cosine wave signal, and the OUTM signal may be a sine wave signal. Other variations are possible.

The oscillator stage 24 includes an oscillator core 30 that, in turn, includes the inductive storage elements for the LC tank of the stage 24 and includes the appropriate switching devices to achieve the desired oscillation. The oscillator stage 24 may also include a modulation input terminal 29. More specifically, the oscillator stage 24a receives a modulation input signal called INM at the input terminal 29; and the oscillator stage 24b receives a modulation signal called INM at the input terminal 29.

For purposes of tuning the oscillation frequency of the oscillator 20, each oscillator stage 24 includes a bank 26 of capacitors 28. In some embodiments of the invention, the capacitors 28 are binarily-weighted. For example, the capacitor 28₁ may have a capacitance of C, the capacitor 28₂ (not depicted in FIG. 2) may have a capacitance of 2C, the capacitor 28_{N-1} may have a capacitance of 2^{N-1} times C, the capacitor 28_{N} may have a capacitance of 2^{N}·C, etc.

To coarsely adjust the operating frequency of the oscillator 20, the capacitors 28 of the capacitor banks 26 are selectively connected together between the two stages 24. For purposes of accomplishing this, the oscillator 20 includes a bank 40 of switches 42. More specifically, the switch 42₁ may be activated to connect the capacitors 28₁ of the banks 26 together, the switch 42_{N-1} may be activated to connect the capacitors 28_{N-1} together, the switch 42_{N} may be activated to connect the capacitors 28_{N}, etc. Thus, each switch 42 is connected between two capacitor terminals, i.e., one terminal from each capacitor bank 26. The terminal of the capacitor 28, which is not connected to a switch 42 is connected to the output terminal 27. For example, one terminal of the capacitor 28₁ is connected to the output terminal 27 of the bank 24a, and the other terminal of the capacitor 28₁ is connected to one terminal of the switch 42₁.

Traditionally, the terminal of the capacitor that is not connected to the output terminal 27 may be selectively connected to ground by a single-ended switch, instead of the differential switch that is described herein. However, single-ended switching requires a switch that has a low resistance, which means the MOSFET that forms the switch may be relative large. In contrast, the switches 42 that are depicted in FIG. 2 carry less current and therefore, may be formed from significantly smaller MOSFET devices.

The oscillator 20, in some embodiments of the invention, includes an additional bank 50 of switches 52 for each oscillator stage 24. The switches 52 are selectively closed to couple otherwise unconnected capacitors (i.e., the capacitors that are not being use to tune the oscillator 20) to ground for purposes of keeping the terminals of the unconnected capacitors from “floating” and are not used for purposes of establishing ground connections to the capacitors that are being used to tune the oscillator 20.

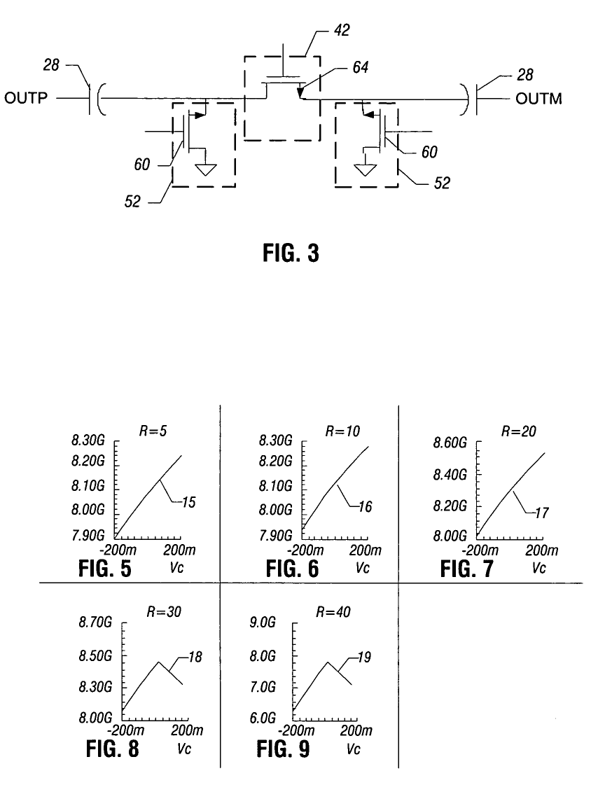

As a more specific example, FIG. 3 depicts a MOSFET-based differential switch structure for connecting two exemplary capacitors 28 (one from each stage 24 together). This structure includes an n-channel MOSFET 64 that is coupled between the capacitors 28. A drain terminal of the MOSFET 64 is coupled to one of the capacitor 28 terminals, and the source of the MOSFET 64 is connected to the terminal of the other capacitor 28. The gate terminal of the MOSFET 64, in turn, receives a control signal to activate the MOSFET 64 to cause the MOSFET 64 to couple the two capacitors 28 together for purposes of tuning. When the capacitors 28 are not being used, MOSFETs 60 are activated to couple the capacitor terminals to ground. More specifically, in some embodiments of the invention, each MOSFET 60 may be a p-channel MOSFET that has its source terminal connected to the drain terminal of the MOSFET 64. The drain terminal of the MOSFET 60, in turn, is connected to ground. Other variations are possible in other embodiments of the invention.

FIGS. 5, 6, 7, 8 and 9 depict tuning curves of an oscillator of the prior art. More specifically, FIG. 5 depicts a tuning curve 15 of an oscillator in which single-ended switches are used to connect the coarse-tuning capacitors to ground. A waveform 15 depicts the tuning curve for a switch resistance of 5 ohms. As shown, in FIG. 5, for this relatively small switch resistance, the tuning curve is relatively monotonic and may be used to vary the frequency of the oscillator stage. Similarly, FIGS. 6 and 7 depict waveforms 16 and 17, respectively, that are monotonic for relatively small resistances of 10 and 20 ohms, respectively. However, in the conventional oscillator topology, in order to achieve these relatively small switch resistances, the corresponding MOSFETs must be relatively large.

A problem occurs when smaller MOSFETs are used and thus, the switch resistances increase. For example, for the conventional topology, FIGS. 8 and 9 depict waveforms 18 and 19 for switch resistances of 30 and 40 ohms, respectively. As can be seen from these figures, for these relatively large switch resistances, the monotonicity of the tuning curve degrades in that for tuning voltages above zero volts, the operating frequency actually decreases, instead of increases, for an increasing tuning voltage.

However, with the differential switch structure described above, the switch resistances may be significantly higher, and may each have switch resistances as high as 30 and 40 ohms (for example), without destroying monotonicity of the tuning curve.

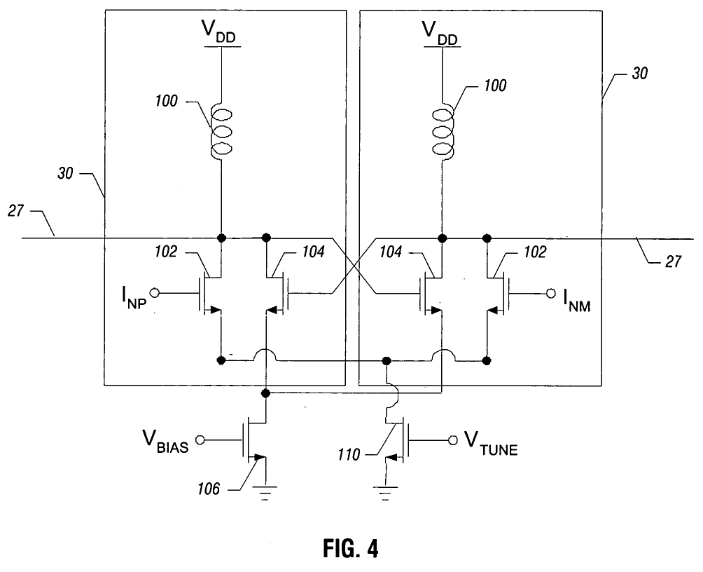

In some embodiments of the invention, the oscillating core 30 (FIG. 2) may have a design that is depicted in FIG. 4. Referring to FIG. 4, this design includes an n-channel MOSFET 102 that has its drain terminal coupled to the output terminal 27. The source terminal of the MOSFET 102 is coupled to the source terminal of the MOSFET 102 of the other core 30. The core 30 also includes another N-channel MOSFET 104 that has its drain terminal coupled to the output terminal 27. The source terminal of the MOSFET 104 is coupled to the drain terminal of a bias n-channel MOSFET 106. The source terminal of the MOSFET 106 is connected to ground, and the gate terminal of the MOSFET 106 receives a signal called “V_{BIAS}.” As its name implies, the MOSFET 106 regulates a current through the drain-source path of the MOSFET 104 to control a bias operating point of the core 30. The oscillator core 30 may also include an indicator 100 that is coupled between the output terminal and a supply voltage called V_{DD}.

In some embodiments of the invention, for purposes of controlling the frequency of the oscillator, both cores 30 share the use of a MOSFET 110 that has a drain that is coupled to the source terminals of the MOSFETs 102. The source terminal of the MOSFET 110 is coupled to ground. The gate terminal of the MOSFET 110 receives a signal called V_{TUNE} whose magnitude controls the oscillation frequency of the oscillator 20.

It is noted that the specific structure that is depicted in FIGS. 2 and 4 is one of many possible embodiments of an oscillator that has capacitors that are used to coarse tune the frequency of the oscillator. Thus, other embodiments that fall within the scope of the appended claims are possible.

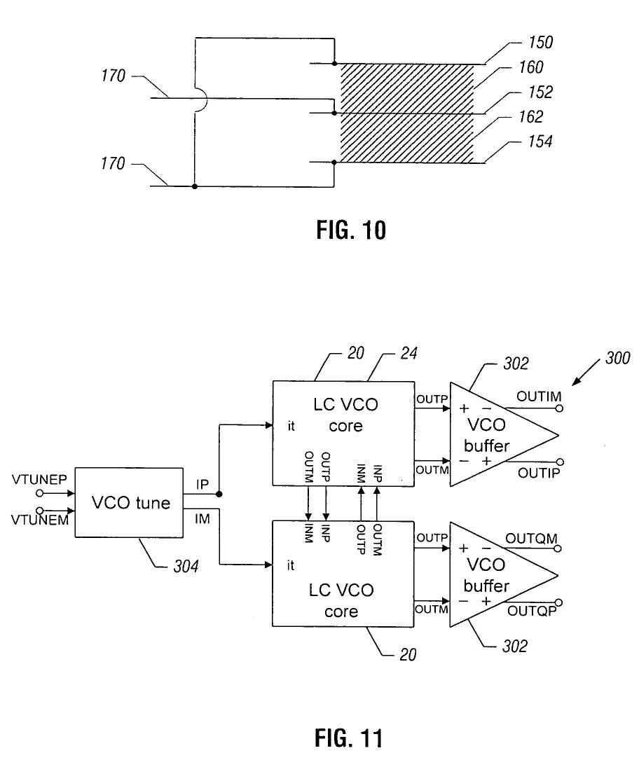

In some embodiments of the invention, the capacitor 28 may be a metal-to-metal capacitor and may be formed by a parasitic capacitance that exists between the metal layers of the semiconductor device in which the oscillator 20 is fabricated. More specifically, referring to FIG. 10, in some embodiments of the invention, each capacitor 28 may be formed from adjacent metal layers 150, 152 and 154 of the semiconductor device. As a more specific example, in some embodiments of the invention, these metal layers 150, 152 and 154 may be upper metal layers (such as the uppermost or top metal layers, for example) of the semiconductor device.

In some embodiments of the invention, for purposes of forming the metal-to-metal capacitor, the conductive portions of the metal layers, 150, 152 and 154 are arranged over each other, with no oxide layer residing between the metal layers. For example, the uppermost metal layer 150 is separated from the middle metal layer 152 by a region 160 of the semiconductor device that does not include an intervening oxide. Similarly, the middle metal layer 162 is separated from the lower metal layer 154 by a region 162 of the semiconductor device that does not include an intervening oxide.

In some embodiments of the invention, for purposes of forming a particular capacitor, the metal layers 150 and 154 may be coupled together for purposes of forming one terminal of the capacitor 28, and the other terminal of the capacitor may be formed from the metal layer 152. As a more specific example, in some embodiments of the invention, the metal layer 152 may be connected to the output terminal 27; and thus, form one terminal 170 of the capacitor 28, and the metal layers 150 and 154 may be connected to one side of the switch 42 and thus, form another terminal 171 of the capacitor 28.

Thus, in some embodiments of the invention, the parasitic capacitance between metal layers is the main component of capacitance of the capacitor 28. The use of metal-to-metal capacitors and the reliance on the parasitic capacitance between the metal layers permits metal layers of the semiconductor device to be used without the need for any specialized analog capacitors. This is possible because the architecture described above is relatively insensitive to process variations in the capacitors because of the coarse-fine tuning mechanism. Furthermore, the architecture described above is easily portable to other processes, as along as several metal layers are available. This approach is to be contrasted to conventional architectures that make use of varactors, which are very-process specific and require careful modeling. Alternatively, specialized analog capacitors may be used. However, these capacitances often are not available or lead to a significant process cost increase.

The oscillator 20, in some embodiments of the invention, provides two orthogonal, single-ended signals. For purposes of generating differential orthogonal signals, two oscillators 20 may be coupled together, as shown in FIG. 11. More specifically, referring to FIG. 11, each oscillator 20 provides its OUTP signal to the INM input terminal 29 of the other oscillator 20. Furthermore, each oscillator 20 provides its OUTM output signal to the INP input terminal 29 of the other oscillator 20. Due to this arrangement, the output terminals of one of the oscillators 20 produces a differential oscillating signal; and the output terminals 27 of the other oscillator 20 produce a differential oscillating signal that is orthogonal with respect to the oscillating signal produced by the other oscillator 20. As depicted in FIG. 11, the oscillator 300 may include buffers 302 to buffer these differential output signals. Furthermore, in some embodiments of the invention, the oscillator 300 may include a tuning circuit 304 to produce the tuning voltages to control the oscillator frequencies.

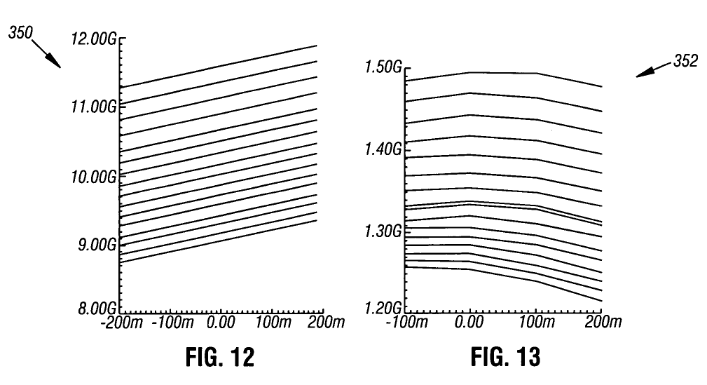

FIG. 12 depicts tuning curves 350 for a first range of frequencies for the oscillator 300. Each one of the curves 350 is for a different switch frequency. As shown, in the frequency ranges depicted in FIG. 12, the tuning curves are monotonic. It is noted that the monotonicity of the tuning curves may be affected for a different range of frequencies, such as a lower frequency range.

More specifically, for lower frequencies, the capacitor resistance begins to dominate, as the capacitance value of each LC tank become smaller relative to the capacitor resistance. This effect is depicted in FIG. 13. More specifically, FIG. 13 depicts tuning curves 352 for a lower frequency range showing the inversion of the tuning curves with respect to the tuning voltage. The tuning curves are monotonic to the point where the switch resistance dominates, and then a subsequent inversion occurs. The use of the differential switch structure is therefore helpful in ensuring this does not happen.

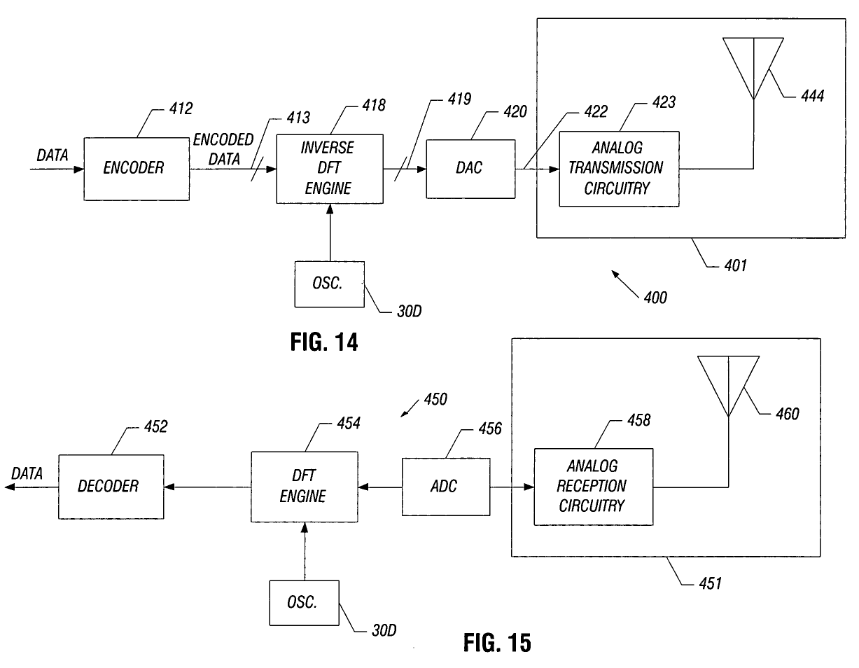

In some embodiments of the invention, the oscillator 300 may be used in an orthogonal frequency division multiplexing architecture (OFDMA) communication interface. More specifically, referring to FIG. 14, in some embodiments of the invention, the oscillator 300 may be part of an OFDMA transmitter 400. In this embodiment of the invention, the transmitter 400 may be used to transmit data over a communication link, such as a cable-based or wireless link (as depicted in FIG. 14), as examples. During its course of operation, an encoder 412 of the transmitter 400 receives data (via communication lines 411) to be transmitted over the communication link, as this data is updated as a predefined sampling rate. The encoder 412 may, for example, introduce an error correcting scheme into the data. The encoder 412 may also perform other operations on the received data, such as a mapping operation, for example. More specifically, in some embodiments of the invention, the encoder 412 may map the data that is received by the encoder 412 into a complex value space using quadrature amplitude modulation (QAM). Other and different operations by the encoder 412 are possible. The encoder 412 provides the encoded data (via communication lines 413) to an Inverse Discrete Fourier Transform (IDFT) engine 418 of the transmitter 400.

The encoded data may be viewed as being divided into segments, with each segment representing a coefficient that is associated with an assigned subcarrier. The IDFT engine 418 modulates these coefficients with the assigned subcarriers to produce a time-varying digital signal. This digital signal, in turn, is communicated (via communication lines 419) to a digital-to-analog converter (DAC) 420 that converts the digital signal into an analog signal. The transmitter 400 also includes analog transmission circuitry 423 that modulates the analog signal with at least one radial frequency carrier signal and transmits the resultant RF signal by driving an antenna 444 (a dipole antenna, for example) in response to the RF signal. The analog transmission circuitry 423 and the antenna 444 thus form a communication interface 401 (a wireless interface, for example) for the transmitter 400.

It is noted that the analog transmission circuitry 423 may also include an oscillator, similar in design to the oscillator 300, in some embodiments of the invention. Furthermore, although FIG. 14 depicts the transmitter 400 as being a wireless transmitter, it is noted that the transmitter 400 may communicate a modulated signal to another type of communication link, such as a cable-based communication link, in some embodiments of the invention.

In some embodiments of the invention, the oscillator 300 may be used in connection with a receiver 450 that receives a modulated signal from a communication link, such as a cable-based communication link or a wireless-based communication link, as depicted in FIG. 15. Referring to FIG. 15, in some embodiments of the invention, the transmitter 450 may include an antenna 460 (a dipole antenna, for example) that furnishes a modulated signal to analog reception circuitry 458. The antenna 460 and the circuitry 458 may form, for example, a wireless interface 451 for the transmitter. In other embodiments of the invention, the interface 451 may form an interface to receive a modulated signal from another type of communication link, such as a cable-based communication link, for example.

Although not depicted in FIG. 15, in some embodiments of the invention, the analog receiver circuitry 450 may include an oscillator, similar to the oscillator 300. The receiver circuitry 458 furnishes a signal form which the RF carrier has been demodulated. This signal is furnished to an analog-to-digital-converter (ADC) 456 that, in turn, furnishes a corresponding digital signal to a Discrete Fourier Transform (DFT) engine 454. The DFT engine 454, in turn, receives orthogonal signals from an oscillator 300. The DFT engine 454 furnishes encoded to a decoder 452 that, in turn, decodes the data to furnish the corresponding decoded and unmodulated data at its output terminals. Other variations are possible in other embodiments of the invention.

While the invention has been disclosed with respect to a limited number of embodiments, those skilled in the art, having the benefit of this disclosure, will appreciate numerous modifications and variations therefrom. It is intended that the appended claims cover all such modifications and variations as fall within the true spirit and scope of the invention.

1. A method comprising:
selectively coupling capacitors of oscillator stages together to set an oscillation frequency.

2. The method of claim 1, wherein the coupling comprises differentially coupling the capacitors together.

3. The method of claim 1, wherein each stage comprises multiple capacitors, the method further comprising:
selectively coupling the capacitors together in pairs to adjust the frequency.

4. The method of claim 3, further comprising:
binarily-weighting the capacitors.

5. The method of claim 1, wherein the coupling comprises:
coupling one terminal of a capacitor from each stage together and coupling another terminal of said capacitor from each stage to an output terminal.

6. The method of claim 1, further comprising:
selectively coupling the capacitors to ground.

7. The method of claim 6, wherein the selectively coupling the capacitors to ground comprises:
coupling the capacitors to ground when not being used to adjust the oscillation frequency.

8. The method of claim 1, further comprising:
using one of the oscillator stages to generate a first output signal; and
using another one of the oscillator stages to generate a second signal orthogonal to the first signal.

9. The method of claim 8, wherein the first and second oscillating signals have the same oscillation frequency.

10. A system comprising:
a first oscillator stage;
a second oscillator stage; and
switches to selectively couple capacitors of the first and second oscillator stages together to adjust an oscillation frequency.

11. The system of claim 10, wherein the switches differentially couple the capacitors together.

12. The system of claim 10, wherein each stage comprises multiple capacitors, wherein the switches selectively couple the capacitors together so that the capacitors when coupled together are connected in a pair.

13. The system of claim 12, wherein the multiple capacitors are binarily-weighted.

14. The system of claim 10, wherein the switches couple one terminal of a capacitor from each stage together and couple another terminal of said capacitor from each stage to an output terminal.

15. The system of claim 10, further comprising:
additional switches to selectively couple the capacitors to ground.

16. The system of claim 15, wherein the switches selectively couple the capacitors to ground that are not being used to adjust the oscillation frequency.

17. The system of claim 10, wherein:
the first oscillator stage generates a first output signal, and
the second oscillator stage generates a second signal orthogonal to the first signal.

18. A method comprising:
selectively activating capacitors to adjust an oscillating frequency of an oscillator; and
for each of the capacitors using parasitic capacitance as the main component of capacitance for the capacitor.

19. The method of claim 18, further comprising:
forming the capacitors from parasitic capacitance exhibited between metal layers of a semiconductor device.

20. The method of claim 18, further comprising:
forming the capacitors from metal-to-metal capacitors.

21. An apparatus comprising:
an oscillation stage; and
capacitors to regulate an oscillation frequency of an oscillator stage, the capacitors being formed primarily from parasitic capacitance.

22. The apparatus of claim 21, wherein the capacitors are formed
from parasitic capacitance exhibited between metal layers of a semiconductor device.

23. The apparatus of claim 21, wherein the capacitors are formed from
forming the capacitors from metal-to-metal capacitors.

24. A system comprising:
a oscillator stage;
a second oscillator stage;
switches to selectively couple capacitors of the first and second stages together to adjust an oscillation frequency; and
a wireless interface to communicate with a communication link in response to at least one oscillation signal provided by at least one of the first and second oscillator stages.

25. The system of claim 24, wherein the wireless interface comprises a dipole antenna.

26. The system of claim 24, further comprising:
a Discrete Fourier Transform engine.
